(19) United States
(12) Patent Application Publication
(10) Pub. No.: US 2025/0391704 A1
(43) Pub. Date: Dec. 25, 2025

(54) METHOD FOR TRANSFERRING A THIN LAYER ONTO A SUPPORT SUBSTRATE

(71) Applicants: Soitec, BERNIN (FR); Commissariat a l’Energie Atomique et aux Energies Alternatives, Paris (FR)

(72) Inventors: Didier Landru, BERNIN (FR); Nadia Ben Mohamed, BERNIN (FR); Oleg Kononchuk, BERNIN (FR); Frédéric Mazen, Grenoble Cedex 09 (FR); Helen Grampeix, Grenoble Cedex 09 (FR)

(21) Appl. No.: 18/834,441

(22) PCT Filed: Dec. 19, 2022
(86) PCT No.: PCT/EP2022/086726

§ 371 Date: Feb. 25, 2025

(30) Foreign Application Priority Data
Jan. 31, 2022 (FR) FR2200842

(51) Int. Cl. H01L 21/762

(52) U.S. Cl. CPC H01L 21/76254

(57) ABSTRACT

A method of transferring a thin layer onto a support substrate comprises the following steps: —supplying a bonded structure comprising a donor substrate and the support substrate, assembled by direct bonding at the respective front faces thereof along a bonding interface, the donor substrate comprising a buried brittle plane, —applying a fracture heat treatment to the bonded structure to induce spontaneous separation along the buried brittle plane, associated with the growth of microcracks in the plane through thermal activation, the separation leading to the transfer of a thin layer from the donor substrate to the support substrate. The fracture heat treatment exhibits: —a temperature-rise rate in excess of 1° C./s, at least between an initial temperature lower than 250° C. and a plateau temperature greater than or equal to 500° C., and —a temperature profile such that the bonded structure is subjected to a temperature gradient varying between 40° C. and 120° C. between a central region and a peripheral region.

### CROSS REFERENCE TO RELATED APPLICATIONS

This application is a national phase entry under 35 U.S.C. § 371 of International Patent Application PCT/EP2022/086726, filed Dec. 19, 2022, designating the United States of America and published as International Patent Publication WO 2023/143818 A1 on Aug. 3, 2023, which claims the benefit under Article 8 of the Patent Cooperation Treaty to French Patent Application Serial No. FR2200842, filed Jan. 31, 2022.

### TECHNICAL FIELD

The present disclosure relates to the field of microelectronics and semiconductors. In particular, the present disclosure relates to a method for transferring a thin film onto a support substrate, based on SMART CUT™ technology, the thin film exhibiting improved roughness after separation. In particular, the transfer method can be used to manufacture an SOI structure.

### BACKGROUND

SMART CUT™ technology is well known for manufacturing SOI (silicon-on-insulator) structures and, more generally, for thin-film transfer. This technology is based on the formation of a brittle plane buried in a donor substrate, by implanting light species into the substrate; the buried brittle plane delimits, with a front face of the donor substrate, the thin film to be transferred. The donor substrate and a support substrate are then joined at their respective front faces to form a bonded structure. The assembly is advantageously carried out by direct bonding, by molecular adhesion, that is, without involving adhesive material: a bonding interface is thus established between the two assembled substrates. The growth of microcracks in the buried brittle plane, through thermal activation, can lead to spontaneous separation along the plane, resulting in the transfer of the thin film onto the supporting substrate (forming the stacked structure, for example, SOI type). The remaining donor substrate can be reused for a subsequent film transfer. After separation, it is usual to apply finishing treatments to the stacked structure, to restore the crystalline quality and surface roughness of the transferred thin film. These treatments are known to involve oxidizing or smoothing heat treatments (under neutral or reducing atmospheres), chemical cleaning and/or etching and/or chemical-mechanical polishing steps. Various inspection tools are available to check the entire surface of the thin film.

When separation in the buried brittle plane is spontaneous, significant variability is observed in terms of the surface roughness of the thin film transferred, both at high frequencies (microroughness) and at low frequencies (rippling, local areas of high roughness, mottling, etc.). These variabilities are visible and measurable, in particular, via the aforementioned inspection tools, when checking the thin film in the final structure.

Recall that the surface roughness of the thin film after finishing can be mapped using a SURFSCAN® inspection tool from KLA-Tencor (FIG. 1). The level of roughness and potential patterns (mottling, dense zones, etc.) are measured or made apparent by measuring the diffuse background noise (“haze”) corresponding to the intensity of light scattered by the surface of the thin film. The haze signal varies linearly with the square of the RMS surface roughness in the spatial frequency range from 0.1 to 10 μm⁻¹. Please refer to the article “Seeing through the haze,” by F. Holsteyns (Yield Management Solutions, Spring 2004, pp 50-54) for more information on this large-area roughness inspection and evaluation technique.

The maps in FIG. 1 show the surface roughness of two thin layers transferred from two bonded structures that are treated identically up to the finish. Map (A) shows a peripheral zone of residual roughness, known as the “dense zone” (ZD); map (B) has none at all. More pronounced mottling (M) is also visible in map (A). Average and maximum roughness (expressed in ppm haze) also differ between the two maps (A) and (B). FIG. 1 shows the variability of the final quality and roughness of thin films, which is mainly due to the variability of surface roughness (high and low frequencies) after separation.

To improve the final quality of the transferred thin films, it is therefore still important to reduce the surface roughness (whatever the spatial frequency) of these layers after transfer, in the case of spontaneous separation by thermal activation.

### BRIEF SUMMARY

The present disclosure proposes a transfer method using a particular fracture heat treatment, enabling improved surface roughness of the thin film after separation, to achieve excellent surface quality after the finishing stages of the stacked structure. The method is particularly advantageous for the manufacture of SOI structures.

The present disclosure relates to a method for transferring a thin film onto a support substrate, comprising the following steps:
supplying a bonded structure comprising a donor substrate and the support substrate, assembled by direct bonding at the respective front faces thereof along a bonding interface, the donor substrate comprising a buried brittle plane, and
applying a fracture heat treatment to the bonded structure to induce spontaneous separation along the buried brittle plane, associated with the growth of microcracks in the plane through thermal activation, the separation leading to the transfer of a thin film from the donor substrate to the support substrate.

The method is notable in that the fracture heat treatment exhibits:
a temperature rise-rate in excess of 1° C./s, at least between an initial temperature lower than 250° C. and a level temperature greater than or equal to 500° C., and
a temperature profile such that the bonded structure is subjected to a temperature gradient varying between 40° C. and 120° C. between a central region and a peripheral region.

According to advantageous features of the present disclosure, taken alone or in any feasible combination:
the transfer method comprises, prior to the fracture heat treatment, a pre-annealing applied to the bonded structure, so as to achieve a pre-ripening of the microcracks in the buried brittle plane, the thermal budget provided by the pre-annealing being insufficient to cause spontaneous separation;
the temperature gradient is between 40° C. and 80° C.;
the transfer method comprises a step of smoothing a front face of the thin film, following separation, by annealing at a temperature in excess of 1000° C., in a neutral or reducing atmosphere, the fracture heat treatment and the smoothing step taking place in the same enclosure and equipment;
the buried brittle plane is formed in the donor substrate by implanting a light species such as hydrogen, helium or a combination of both;
the donor substrate and/or the support substrate have an insulating layer, at least on the respective front side thereof, which forms a buried insulating layer adjacent to the bonding interface in the bonded structure;
the thin film from the donor substrate is monocrystalline silicon and the support substrate comprises monocrystalline silicon, to form a stacked SOI structure.

### BRIEF DESCRIPTION OF THE DRAWINGS

Other features and advantages of the present disclosure will emerge from the following detailed description of example embodiments of the present disclosure with reference to the appended figures, in which:

FIG. 1 shows two representative surface roughness maps of two transferred thin layers, from two bonded structures treated identically until finishing, using a conventional method; both maps were obtained via a SURFSCAN® inspection tool;

FIG. 2 shows a graph indicating the surface roughness of thin layers as a function of fracture time, for a plurality of bonded structures (of a different type from the bonded structures shown in reference to FIG. 1) treated identically until finishing, according to a conventional method;

FIG. 3 shows a bonded structure used in an intermediate stage of the transfer method according to the present disclosure;

FIG. 4 shows a stacked structure and the remainder of a donor substrate, obtained by a transfer method in accordance with the present disclosure;

FIG. 5 shows an example of a temperature profile during a fracture heat treatment implemented in a transfer method in accordance with the present disclosure; and

FIG. 6 shows two representative surface roughness maps of two transferred thin films of a first (left) and a second (right) SOI structure, the first having been obtained with a conventional transfer method and the second with a transfer method in accordance with the present disclosure; both maps were obtained via a SURFSCAN® inspection tool.

Some figures are schematic depictions that, for the sake of readability, are not to scale. In particular, the thicknesses of the layers along the z axis are not to scale with respect to the lateral dimensions along the x and y axes.

The same references in the figures or description may be used for elements of the same type.

### DETAILED DESCRIPTION

The present disclosure relates to a method for transferring a thin film onto a support substrate, to form a stacked structure. As mentioned in the introduction, such a stacked structure can be of the SOI type, comprising a thin silicon surface layer, an intermediate insulating layer and a silicon support substrate. The support substrate may optionally comprise other functional layers, such as a charge trapping layer, for example, for SOI structures designed for radio frequency applications. The transfer method described here is not limited to the manufacture of SOI, however, and can be applied to many other stacked structures in the field of microelectronics, microsystems and semiconductors.

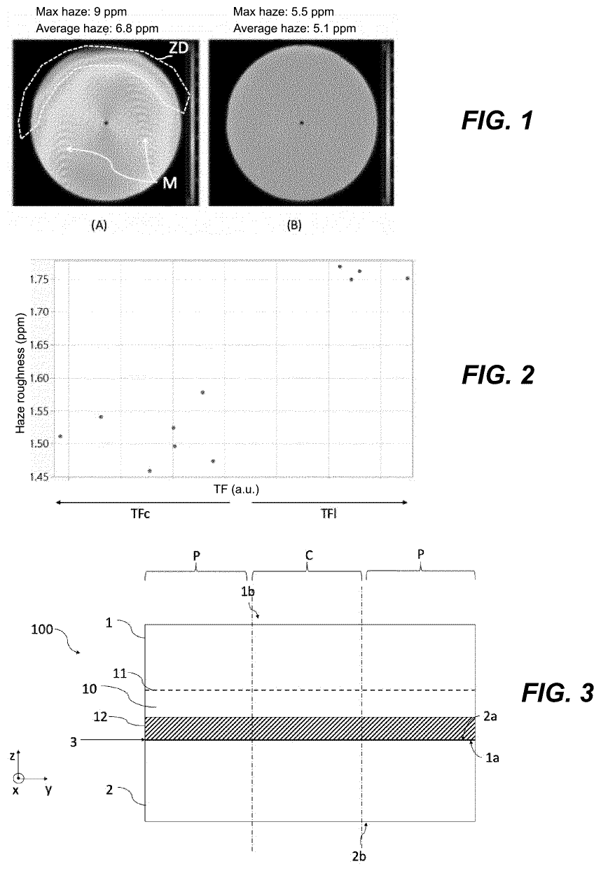

The transfer method according to the present disclosure is based on SMART CUT™ technology. When separation in the buried brittle plane is spontaneous, the fracture time (that is the time after which separation occurs, during thermal fracture annealing) may differ between a plurality of identically treated bonded assemblies, undergoing the same annealing, in the same furnace. The fracture time (TF) depends on a multitude of parameters linked to the formation of the buried brittle plane, the fracture annealing, the nature of the bonded structure, etc. It has been noted that, for similarly prepared bonded structures undergoing the same fracture annealing, separations occurring at short fracture times (TFc) result in thin layers having lower high-frequency surface roughness (microroughness) in the final stacked structures (that is after transfer and finishing) than separations occurring at longer fracture times (TFl), as can be seen in FIG. 2. Furthermore, long fracture times induce a local zone of very high roughness (called the dense zone ZD) at the edge of the thin film after fracture, which is not the case or rarely so when the fracture time is short. This dense zone degrades the quality and roughness of the thin film, even after finishing, as can be seen in map (A) in FIG. 1.

The transfer method according to the present disclosure therefore aims to initiate spontaneous separation in the buried brittle plane in an early (short fracture time) and repeatable (low fracture time dispersion between a plurality of similar bonded structures) manner, so as to substantially improve the surface roughness of the transferred thin film.

To this end, the transfer method comprises firstly providing a bonded structure 100 comprising a donor substrate 1 and the support substrate 2, assembled by direct bonding at their respective front faces (1a, 2a), along a bonding interface 3 (FIG. 3).

The donor substrate 1 is preferably in the form of a wafer with a diameter of 100 mm, 150 mm, 200 mm, 300 mm or even 450 mm, and with a thickness typically between 300 μm and 1 mm. It comprises a front face 1a and a rear face 1b. The surface roughness of the front face 1a is chosen to be less than 1.0 nm RMS, preferably even less than 0.5 nm RMS (measured by atomic force microscopy (AFM), for example, on a 20 μm×20 μm scan). The donor substrate 1 can be made of silicon or any other semiconductor or insulating material for which thin film transfer may be of interest (for example, SiC, GaN, etc.).

It should also be noted that the donor substrate 1 may comprise one or more additional layers 12, at least on its front face 1a, such as an insulating layer. As shown in FIG. 3, this additional layer 12 becomes a buried intermediate layer in the bonded structure 100, after assembling the donor substrate 1 and the support substrate 2.

The donor substrate 1 comprises a buried brittle plane 11, which delimits a thin film 10 to be transferred. As is well known with reference to SMART CUT™ technology, such a buried brittle plane 11 can be formed by implanting light species, such as hydrogen, helium or a combination of both. The light species are implanted at a determined depth in the donor substrate 1, consistent with the thickness of the targeted thin film 10. These light species will form, around the determined depth, microcavities distributed in a thin film substantially parallel to the front face 1a of the donor substrate 1, or parallel to the plane (x, y) in the figures. This thin film is called the buried brittle plane 11, for simplicity's sake.

The implantation energy of the light species is chosen so as to reach the determined depth. For example, hydrogen ions will be implanted at an energy of between 10 keV and 210 keV, and at a dose of between 5E16/cm² and 1E17/cm², to delimit a thin film 10 having a thickness on the order of 100 to 1500 nm. Recall that an additional layer may be deposited on the front face 1a of the donor substrate 1, prior to the ion implantation step. This additional layer may be composed of a material such as silicon oxide or silicon nitride, for example. It may be retained for the next assembly step (and form all or part of the intermediate layer of the bonded structure 100), or it may be removed.

The support substrate 2 is also preferably in the form of a wafer with a diameter of 100 mm, 150 mm, 200 mm, 300 mm or even 450 mm, and with a thickness typically between 300 μm and 1 mm. It comprises a front face 2a and a rear face 2b. The surface roughness of the front face 2a is chosen to be less than 1.0 nm RMS, preferably even less than 0.5 nm RMS (measured by AFM, for example, on a 20 μm×20 μm scan). The support substrate 2 can be made of silicon or any other semiconducting or insulating material, for which thin-film transfer may be of interest. In the context of the present disclosure, the material(s) making up the support substrate 2 must be compatible with applying temperatures greater than or equal to 400° C. to the bonded structure 100 resulting from the assembly of the donor substrate 1 and the support substrate 2.

It should also be noted that the support substrate 2 may comprise one or more additional layers, at least on its front face 2a, for example, an insulating and/or charge-trapping layer. This (or these) additional layer(s) is (are) buried in the bonded structure 100, after assembling the donor substrate 1 and the support substrate 2.

The assembly between the donor substrate 1 and the support substrate 2 is based on direct bonding by molecular adhesion. As is well known per se, such bonding does not require an adhesive material, as atomic-scale bonds are established between the joined surfaces, forming the bonding interface 3. Several types of molecular adhesion bonding exist, which differ, in particular, by their temperature, pressure, atmosphere conditions or treatments prior to contacting the surfaces. Mention may be made of bonding at room temperature with or without prior plasma activation of the surfaces to be assembled, atomic diffusion bonding (ADB), surface-activated bonding (SAB), etc.

The assembly step may comprise, prior to the contacting of the front faces 1a, 2a to be assembled, conventional chemical cleaning sequences (for example, RCA cleaning), surface activation (for example, oxygen or nitrogen plasma) or other surface preparations (such as cleaning by scrubbing), capable of promoting the quality of the bonding interface 3 (few defects, strong adhesion energy).

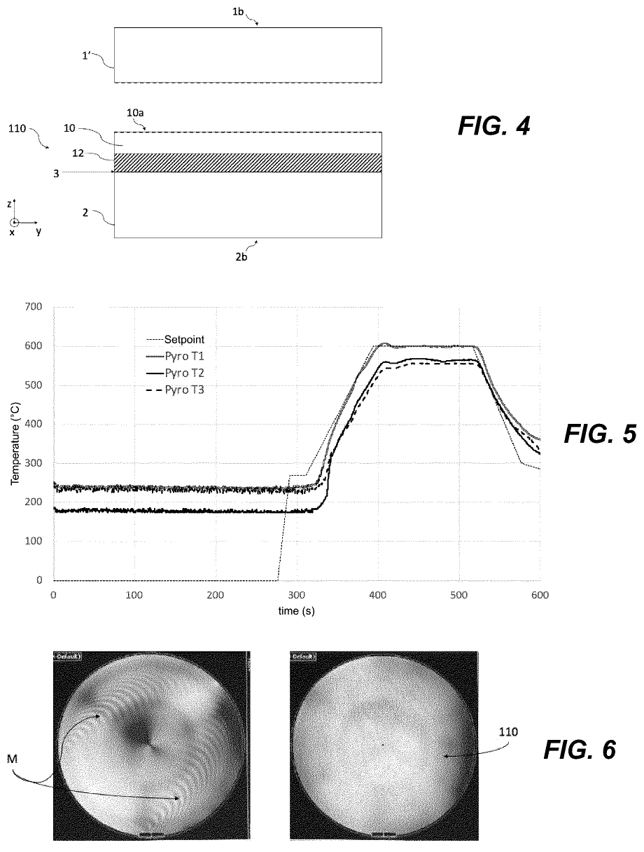

Once the bonded structure 100 has been formed, the transfer method according to the present disclosure involves applying a fracture heat treatment to induce spontaneous separation along the buried brittle plane 11. Separation leads to the transfer of the thin film 10 from the donor substrate 1 to the support substrate 2, to form the stacked structure 110 (FIG. 4). The remainder 1′ of the donor substrate is also obtained.

The thermal fracture treatment according to the present disclosure is special in that it features a very rapid temperature rise-rate and a temperature profile configured to overheat the center of the bonded structure 100 relative to its periphery.

In essence, the temperature rise-rate of the fracture heat treatment is greater than 1° C./s, at least between an initial temperature, below 250° C., and a plateau temperature, greater than or equal to 500° C.

To achieve rapid temperature rise-rates, it is advantageous to use rapid annealing equipment, such as furnaces known as RTA (“Rapid Thermal Annealing”) or RTP (“Rapid thermal Processing”) furnaces, widely used in the semiconductor and microelectronics fields. Heating in this type of equipment is provided by infrared lamps whose power is adjustable so as to adjust the temperature in different zones in relation to the structure being treated.

In RTA or RTP equipment, the initial temperature when the bonded structure 100 is introduced into the furnace chamber is usually room temperature. The temperature rise-rate can also be rapid, typically on the order of 1° C./s up to around 200° C.-250° C. However, as the ripening of microcavities and microcracks in the buried brittle plane 11 is generally slow at temperatures below 250° C., the temperature rise-rate up to 250° C. is not critical.

At least from 250° C., the method according to the present disclosure provides for a rapid rise-rate (>1° C./s) up to the plateau temperature, which is greater than or equal to 500° C. The plateau temperature is typically between 500° C. and 600° C., particularly when the donor substrate 1 is made of silicon. Above 250° C., the kinetics of microcrack growth in the buried brittle plane 11 are significant.

The fracture heat treatment is further defined so that the bonded structure 100 undergoes a temperature gradient varying between 40° C. and 120° C. between a central region C and a peripheral region P. Central region C means a region encompassing the center of the bonded structure 100, in the plane (x,y) parallel to the bonding interface 3 (FIG. 3). The radius (in the (x,y) plane) of the central region C is typically between 1% and 50% of the radius of the bonded structure 100. The peripheral region P is a region surrounding the central region C and encompassing the edges of the bonded structure 100.

Note that a rapid temperature rise-rate up to 250° C. may be advantageous to help establish and maintain the thermal gradient in the next fracture heat treatment sequence, between 250° C. and the plateau temperature.

Preferably, the thermal gradient between the central region C and the peripheral region P is between 40° C. and 80° C.

An example of the temperature profile as seen by the bonded structure 100 during fracture heat treatment is shown in FIG. 5. The initial temperature is room temperature, the plateau temperature is 600° C., as indicated by the setpoint curve. Three monitoring pyrometers T1, T2, T3, located at different points on the bonded structure 100, enable the temperature rise and gradient undergone by the structure to be observed: The pyrometer T1 is positioned at the center, the pyrometers T2, T3 are positioned at the periphery (20 mm from the edge of the bonded structure 100). It should be noted that the pyrometers used give reliable measurements only from 250° C.-300° C. The heating is adjusted in the different zones of the furnace opposite the bonded structure 100, so as to establish a temperature gradient of around 50° C. between the central region C (see temperature curve of pyrometer T1) and the peripheral region P (see temperature curves of pyrometers T2, T3).

The temperature gradient applied to the bonded structure 100 induces local overheating in the central region C during the fracture heat treatment, which leads to greater ripening of the microcracks in the buried brittle plane 11 in this region, compared to the peripheral region P. The greater ripening of the microcracks in the central region C acts as a fracture initiator during the rapid temperature rise, approaching the plateau temperature.

This brings the advantage of propagation of the separation wave from the center to the edges of the bonded structure 100, which greatly limits the amplitude of mottling M or other fracture waves (roughness and low-frequency ripples) on the surface of the transferred thin film 10. Another advantage is that separation occurs early, with a shorter fracture time than the conventional fracture time for a similar bonded structure undergoing conventional fracture annealing. Early fracture ensures low microroughness (high spatial frequency) and few, if any, local areas of high roughness (otherwise known as dense zones ZD).

The roughness improvement achieved by implementing the transfer method according to the present disclosure is shown in FIG. 6. The first map shows the surface roughness of a thin film transferred into a first SOI structure obtained with a conventional transfer method (including a finishing step): the presence of mottling and fracture waves on the surface is noted. The second map shows a second SOI structure 110, obtained with a transfer method in accordance with the present disclosure (including a finishing step). The SOI structure 110 is free from mottling M or other dense zones ZD.

The transfer method according to the present disclosure also enables high rates of fracture heat treatment to be achieved, thanks to the very short duration of these treatments.

In an advantageous embodiment of the transfer method, pre-annealing is applied to the bonded structure 100, prior to the fracture heat treatment, so as to achieve a pre-ripening of the microcavities and microcracks in the buried brittle plane 11. However, the thermal budget provided by pre-annealing remains insufficient to bring about spontaneous separation. Typically, the aim is for a thermal budget for this pre-ripening of between 25% and 75% of the thermal budget for fracture leading to spontaneous separation. In the case of a silicon donor substrate, the pre-annealing temperature is preferably set at around 350° C.

Pre-annealing can be carried out in a conventional horizontal or vertical furnace, or in an RTA or RTP furnace. It is important that pre-ripening takes place as homogeneously as possible within the buried brittle plane 11, whatever the region of the plate (central or peripheral).

Pre-ripening the microcracks in the buried brittle plane 11 can further improve the surface roughness of the thin film 10 after separation by reducing the gap in microcrack maturity that will be present at the time of separation initiated by the thermal gradient (applied during the fracture heat treatment). To act as a fracture initiator, it is essential to establish a significant temperature gradient between the central region C and the peripheral region P; such a gradient can induce significant differences in microcrack ripening during the rapid temperature rise. If the microcracks in the peripheral region of the buried brittle plane 11 do not mature sufficiently when the fracture wave propagates, mottling-type defects are generated, which is therefore unfavorable. Thus, for very high thermal gradients applied in the fracture heat treatment rise (for example, above 50° C., or even above 80° C.), it is advantageous to carry out the ripening pre-annealing, which will bring the entire buried brittle plane 11 to a level of maturity compatible with fracture propagation without generating mottling.

The transfer method according to the present disclosure may also comprise a step of smoothing the front face 10a of the thin film 10, following separation.

This step eliminates the surface roughness caused by fracture in the buried brittle plane 11, and restores the crystalline quality of the transferred thin film. The stacked structure 110, obtained after separation, is usually removed from the furnace wherein the fracture heat treatment was carried out, to be thermally, chemically and/or mechano-chemically treated in a conventional finishing step.

Advantageously, the smoothing step of the transfer method here comprises the application of annealing at a temperature above 1000° C., in a neutral or reducing atmosphere, directly following the fracture heat treatment, without removing the stacked structure 110 from the furnace enclosure where it underwent the fracture treatment, or even descending back to ambient temperature. The stacked structure 110 and the remainder 1′ of the donor substrate remain close to one another, albeit separate, thus providing a perfectly controlled “local” atmosphere opposite the fractured surfaces. This local atmosphere is essentially formed by implantation gases and is perfectly non-oxidizing: the surface of thin film 10 is therefore absolutely free of oxidation and can be smoothed extremely effectively, that is at lower temperatures than surfaces even lightly coated with native oxide.

The smoothing stage is thus preferably carried out in the same furnace and enclosure as the separation stage, with temperature increases in the 1000° C.-1200° C. range. The atmosphere in the furnace chamber is neutral or reducing (preferably Ar, H2, Ar/H2).

In this stage (unlike the fracturing stage), it is ensured that the temperature experienced by the stacked structure 110 is uniform and homogeneous over the entire surface, as a temperature gradient between center and edge is detrimental at this stage.

The in situ sequence of the fracture heat treatment and the smoothing step in the same furnace enclosure, without any temperature drop and without any return to the outside atmosphere, is particularly advantageous as it ensures very low contamination of the surface of the transferred thin film 10, a total absence of native oxide and consequently very high smoothing efficiency, which also benefits from reduced roughness after separation due to early fracture initiation.

RTA and RTP furnaces are perfectly suited to this type of sequence, which requires rapid ramping (fracture heat treatment) and high temperature rise (smoothing stage). This sequence of steps is an asset in terms of productivity.

### Example Embodiment

In particular, the transfer method can be used to produce an FDSOI (fully depleted SOI) structure, which is one with a thin surface film and a thin buried insulating layer.

The donor substrate 1 is a single-crystal silicon wafer with a diameter of 300 mm, and comprises a 35 nm-thick insulating layer 12 of silicon oxide on its front face 1a. The buried brittle plane 11 is formed by co-implantation of helium and hydrogen ions at energies of 35 keV and 25 keV, respectively, and at doses of 1E16/cm² and 1E16/cm², respectively.

The support substrate 2 is a monocrystalline silicon wafer with a diameter of 300 mm.

A conventional surface preparation (cleaning, plasma activation) of the two substrates 1, 2 is then carried out with a view to molecular adhesion bonding.

Assembly, based on direct contact between the front faces 1a, 2a of the donor and support substrates 2, produces a bonded structure 100.

The bonded structure 100 is introduced into an RTP furnace for thermal fracture treatment in the following sequence:
1. Creating a vacuum in the enclosure
2. Filling with nitrogen N2: 20 s
3. Temperature rise from ambient temperature to 270° C.: 15 s
4. Stabilization at 270° C.: 20 s
5. Temperature rise from 270° C. to 600° C.: 4° C./s
6. Annealing at 600° C. plateau: 120 s
7. Temperature drop (600° C. to 300° C.): 60 sec
8. Temperature drop (300° C. to room temperature): 450 sec

The heating zones of the RTP furnace are adjusted so as to apply a temperature gradient of around 50° C. between the center and the peripheral region P of the bonded structure 100. The local superheating in the central region C acts as a fracture initiator and early separation takes place during the fracture heat treatment, typically at the end of the temperature rise (step 5 in the above sequence).

The surface quality 10a of the transferred thin film 10 is improved compared with an SOI structure obtained from a bonded structure treated by a conventional method, as it has no mottling M or dense zones ZD, or very little. The level of microroughness (“haze”) of the face of a thin film 10 after smoothing is also lower than the level of roughness obtained by a conventional method.

Of course, the present disclosure is not limited to the described embodiments and variant embodiments may be envisaged without departing from the scope of the invention as defined by the claims.

1. A method of transferring a thin film onto a support substrate, comprising the following steps:
supplying a bonded structure comprising a donor substrate and the support substrate, assembled by direct bonding at respective front faces thereof along a bonding interface, the donor substrate comprising a buried brittle plane; and
applying a fracture heat treatment to the bonded structure to induce spontaneous separation along the buried brittle plane due to growth of microcracks in the plane through thermal activation, the separation leading to transfer of a thin layer from the donor substrate onto the support substrate, the fracture heat treatment having:
a temperature rise-rate of in excess of 1° C./s, at least between an initial temperature lower than 250° C. and a plateau temperature greater than or equal to 500° C., and
a temperature profile such that the bonded structure is subjected to a temperature gradient varying between 40° C. and 120° C. between a central region and a peripheral region.

2. The method of claim 1, further comprising, prior to the fracture heat treatment, a pre-annealing applied to the bonded structure, so as to achieve a pre-ripening of the microcracks in the buried brittle plane, the thermal budget provided by the pre-annealing being insufficient to cause spontaneous separation.

3. The method of claim 2, wherein the temperature gradient is between 40° C. and 80° C.

4. The method of claim 3, further comprising a step of smoothing a front face of the thin layer, following separation, by annealing at a temperature in excess of 1000° C., in a neutral or reducing atmosphere, the fracture heat treatment and the smoothing step taking place in the same enclosure.

5. The method of claim 4, further comprising forming the buried brittle plane in the donor substrate by implanting light atomic species in the donor substrate.

6. The method of claim 5, further comprising forming an insulating layer on the front face of the donor substrate and/or the front face of the support substrate, the insulating layer forming a buried insulating layer, adjacent to the bonding interface, in the bonded structure.

7. The method of claim 6, wherein the thin layer from the donor substrate is made of monocrystalline silicon, and the support substrate comprises monocrystalline silicon, to form a stacked SOI structure.

8. The method of claim 5, further comprising selecting the light atomic species to comprise hydrogen, helium, or a combination of hydrogen and helium.

9. The method of claim 1, wherein the temperature gradient is between 40° C. and 80° C.

10. The method of claim 1, further comprising a step of smoothing a front face of the thin layer, following separation, by annealing at a temperature in excess of 1000° C., in a neutral or reducing atmosphere, the fracture heat treatment and the smoothing step taking place in the same enclosure.

11. The method of claim 1, further comprising forming the buried brittle plane in the donor substrate by implanting light atomic species in the donor substrate.

12. The method of claim 1, further comprising forming an insulating layer on the front face of the donor substrate and/or the front face of the support substrate, the insulating layer forming a buried insulating layer, adjacent to the bonding interface, in the bonded structure.

13. The method of claim 1, wherein the thin layer from the donor substrate is made of monocrystalline silicon, and the support substrate comprises monocrystalline silicon, to form a stacked SOI structure.
